(19) United States
(12) Patent Application Publication
(10) Pub. No.: US 2012/0119268 A1
(43) Pub. Date: May 17, 2012

(54) Mixed Junction Source/Drain Field-Effect-Transistor and Method of Making the Same

(75) Inventors: Dongping Wu, Shanghai (CN); Shi-Li Zhang, Stockholm (SE); Liang Ge, Shanghai (CN); Zhi-Jun Chou, Shanghai (CN)

(73) Assignee: FUDAN UNIVERSITY, Shanghai (CN)

(21) Appl. No.: 13/255,498

(22) PCT Filed: Jan. 4, 2011
(86) PCT No.: PCT/CN11/00013

§ 371 Date: Sep. 8, 2011

(30) Foreign Application Priority Data
Jan. 21, 2010 (CN) 201010023067.9
Jan. 4, 2011 (CN) PCT/CN2011/000013

(51) Int. Cl. H01L 29/78; H01L 21/336

(52) U.S. Cl. 257/288; 438/303; 257/E29.255; 257/E21.409

(57) ABSTRACT

The present invention is related to microelectronic technologies, and discloses specifically a mixed junction source/drain field-effect-transistor and methods of making the same. The field-effect-transistor with mixed junction source/drain comprises a semiconductor substrate, a gate structure, sidewalls, and source and drain regions having mixed junction structures, which are combinations of Schottky and P-N junctions. Compared with Schottky junction field-effect-transistors, the mixed junction source/drain field-effect-transistor described in the present invention has the characteristics of relatively low source/drain leakage. At the same time, this field-effect-transistor has lower source/drain series resistances than that associated with P-N junction field-effect-transistors.

### FIELD

The present invention is related to microelectronic technologies, and more particularly to semiconductor devices and methods of making the same.

### BACKGROUND

MOS field-effect-transistor (MOSFET) is short for metal-oxide-semiconductor field-effect-transistor, which is a kind of semiconductor device that controls electrical current in semiconductor using electric field effect. It is also called unipolar transistor because it relies on one type of charge carrier to participate in conducting electric current. MOS field-effect-transistors can be built using semiconductor materials such as silicon and germanium, or semiconductor compounds such as gallium arsenide. Currently, silicon is mostly used. Typically, a MOS field-effect-transistor is comprised mainly of a semiconductor substrate, source and drain, a gate oxide layer and a gate electrode. Its basic structure is generally a four-terminal device, and its middle part has a MOS capacitor structure comprised of metal-insulator-semiconductor. The source and drain are on two sides of the MOS capacitor. In normal operation mode, charge carriers enter through the source and exit through the drain. Above the insulator layer is the gate electrode. By applying a voltage to the gate electrode, the strength of the electric field in the insulator layer can be changed, and the electric field at the surface of the semiconductor can be controlled, thereby changing the conductivity of a surface channel.

The source and drain regions of a conventional MOS field-effect-transistor are purely heavily doped P-N junction structures. This type of P-N junctions can be made using diffusion, ion implantation and/or other fabrication processes, in which the source and drain regions of the field-effect-transistor in the semiconductor substrate are doped with specified amount of impurities. The field-effect-transistor having such source/drain structures, however, tends to have relatively large serial resistances and serious short-channel effect, and is not easy to scale during miniaturization.

If metal silicide source and drain are used to replace the conventional P-N junction source/drain structures in future super miniaturized CMOS devices, the properties of field-effect-transistors can be improved to a certain degree. Metal silicide source and drain are referred to source and drain made of a metal silicide material, which form Schottky junctions with the semiconductor substrate. Their main advantages are low parasitic resistances, good scalability during miniaturization, ease of fabrication, low thermal budget, and better protection against latch up or floating body effect for silicon-on-insulator (SOI) type of devices. The field-effect-transistors with purely Schottky junction source/drain structures, however, have many hidden problems. Schottky junctions have extra leakage current and soft breakdown. Currently, the reliability of field-effect-transistors with such source/drain structures has not been studied properly.

### SUMMARY

In order to solve the problems of high source-drain series resistances associated with conventional heavily doped P-N junction source/drain field-effect-transistors and high source/drain leakage associated with Schottky junction source/drain field-effect-transistors, the present invention provides a mixed junction source/drain field-effect-transistor.

The present invention provides a field-effect-transistor, comprising a semiconductor substrate, a gate structure, sidewalls, and source and drain having at least one mixed junction structure. Each mixed junction is a combination of a Schottky junction and a P-N junction.

Preferably, a switching property of the field-effect-transistor is determined by the Schottky junction in the mixed junction.

Preferably, the semiconductor substrate is a silicon substrate, the Schottky junction is formed between a metal silicide and the silicon substrate, and the P-N junction is formed by implanting into the semiconductor substrate a different type of dopant ions from those used to dope the semiconductor substrate and by subsequent annealing, the metal silicide forming Ohmic contacts with a highly-doped region in the P-N junction.

Preferably, the semiconductor substrate is a germanium substrate, the Schottky junction is formed between a metal germanide and the germanium substrate, and the P-N junction is formed by implanting into the semiconductor substrate a different type of dopant ions from those used to dope the semiconductor substrate and by subsequent annealing, the metal germanide forming Ohmic contacts with a highly-doped region in the P-N junction.

The present invention further provides a method of making the mixed junction source/drain field-effect-transistor. The method comprises:
providing a semiconductor substrate, and forming isolating structures using shallow trench isolation;
forming a first dielectric layer, forming an electrode layer over the first dielectric layer, and forming a gate structure afterwards using patterned etching of the electrode layer and the dielectric layer using photolithography and etch processing;
depositing a second dielectric layer, and etching the second dielectric layer using an anisotropic dry etching process, thereby forming first sidewall structures on two sides of the gate structure;
implanting ions to form P-N junctions in the semiconductor substrate, and annealing to active the implanted ions;
removing the first sidewall structures on the two sides of the gate structure by etching, depositing a third dielectric layer, and etching the third dielectric layer using an anisotropic dry etching process, thereby forming second sidewall structures; and
depositing a metal layer, annealing to cause the metal layer to react with the underlying semiconductor substrate to form a metal-semiconductor compound, and removing unreacted part of the metal layer.

Preferably, the first dielectric layer includes any of silicon dioxide, silicon nitride, aluminum oxide, a hafnium-containing high-K dielectric, and a zirconium-containing high-K dielectric, or a multilayer structure of a combination of two or more thereof.

Preferably, the electrode layer includes at least one conductive layer, the conductive layer being any of polysilicon, titanium nitride, tantalum nitride, tungsten, a metal silicide, or a multilayer structure of a combination of two or more thereof.

Preferably, the metal-semiconductor compound forms a Schottky junction with the semiconductor substrate, and at the same time, forms an Ohmic contact with highly-doped regions of the P-N junctions.

Preferably, the semiconductor substrate is a silicon substrate; the metal layer includes any of nickel, cobalt, titanium, and platinum, or a combination of two of more thereof; and the metal-semiconductor compound includes any of nickel silicide, cobalt silicide, titanium silicide, and platinum silicide, or a combination of two or more thereof.

Preferably, the semiconductor substrate is a germanium substrate, and the metal layer includes any of nickel, cobalt, titanium, and platinum, or a combination of two of more thereof; and the metal-semiconductor compound includes nickel germanide, cobalt germanide, titanium germanide, and platinum germanide, or a combination of two or more thereof.

The field-effect-transistor according to the present invention has relatively low source/drain leakage currents compared with Schottky junction source/drain field-effect-transistors and relatively low source-drain series resistances compared with conventional heavily doped P-N junction source/drain field-effect-transistors.

These objectives and the contents and characteristics of the present invention will be explained in more detail in the following with reference to the drawings, which illustrate exemplary processes. In the drawings, same reference numerals are used to denote same components.

### BRIEF DESCRIPTION OF THE DRAWINGS

FIG. 1 is a flow diagram illustrating a process for making a mixed junction source/drain field-effect-transistor according to embodiments of the present invention.

FIG. 2-a to FIG. 2-m are cross-sectional diagrams illustrating sequential exemplary process steps for making the mixed junction source/drain field-effect-transistor according to embodiments of the present invention.

### DESCRIPTION OF THE EMBODIMENTS

Following are detailed description of exemplary processes for fabricating a mixed junction source/drain field-effect-transistor according to embodiments of the present invention with reference to the drawings.

In the following description, to save from repeated explanations of the components, same reference numerals are used to denote same components. In the drawings, for ease of explanation and observation of the process flows according to embodiments of the present invention, different layers and regions are enlarged or minimized differently, so the sizes shown in the drawings do not represent actual sizes or their relative proportions. The drawings illustrate preferred embodiments of the present invention, but the specific shapes of the regions should not limit the illustrated embodiments. Instead, the embodiments include different shapes resulted, for example, from deviations in actual fabrication processes. For example, surface profiles obtained from etching usually have curving or rounding characteristics, but are instead represented by rectangular shapes because the drawings are illustrative.

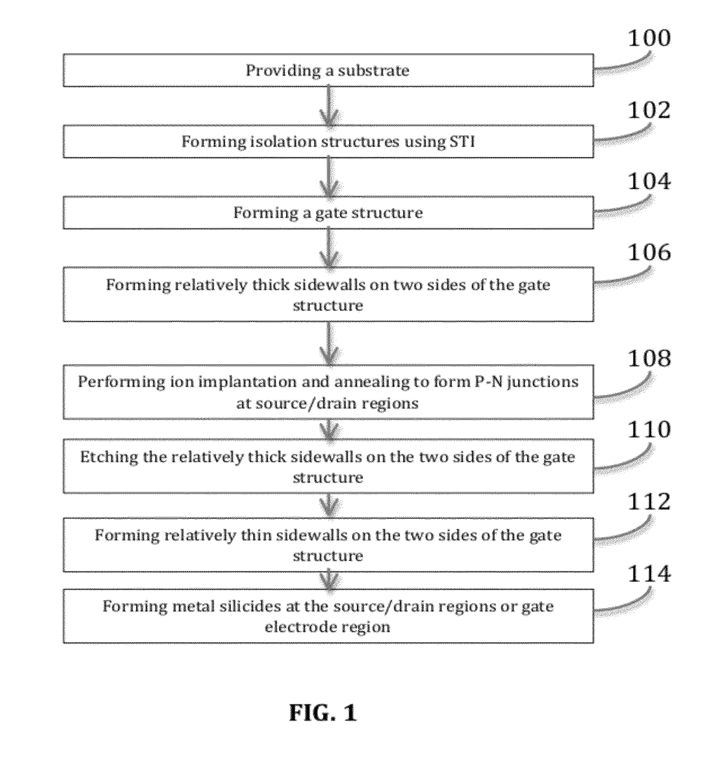

FIG. 1 is a flow diagram illustrating a process for making the mixed junction source/drain field-effect-transistor according to embodiments of the present invention.

In step 100, a semiconductor substrate is provided. The mixed junction source/drain field-effect-transistor according to embodiments of the present invention is formed on the semiconductor substrate.

In step 102, isolation structures are formed on the semiconductor substrate using shallow trench isolation (STI) structures.

In step 104, a gate structure is formed over the semiconductor substrate having the above isolation structures formed thereon. Step 104 includes forming an insulator layer on a surface of the semiconductor substrate and depositing an electrode layer over the insulator layer, followed by photolithography and etching processing to form the gate structure.

In step 106, sidewalls are formed on two sides of the gate structure. An insulating dielectric layer having a thickness of d1 is deposited over the semiconductor substrate and anisotropically etched using a dry etching process. Remaining portions of the insulating dielectric layer form first sidewall structures along a vertical direction of the gate structure.

In step 108, P-N junctions are formed by ion implantation and annealing. Ions are implanted into parts of the semiconductor substrate not protected by the sidewalls on the two sides of the gate structure. The semiconductor substrate undergoes annealing afterwards, causing the ions to be activated.

In step 110, the first sidewalls are etched to remove the first sidewalls on the two sides of the gate.

In step 112, second sidewall structures are formed on the two sides of the gate electrode. An insulating dielectric layer having a thickness of d2 (d2>d1) is first deposited and then anisotropically etched using a dry etching process. Part of the insulating dielectric layer remains after the etching process to form the second sidewall structure along a vertical direction of the gate structure. The second sidewall structures are thinner than the first sidewall structures.

In step 114, metal silicide is formed simultaneously at the source and drain or gate electrode regions. A metal layer is deposited on two sides of the gate electrode protected by the sidewalls, and forms metal silicide with the semiconductor substrate underneath during subsequent annealing. Part of the metal layer not having reacted with the semiconductor substrate during annealing is removed afterwards, leaving a metal silicide layer on the surface of the semiconductor substrate.

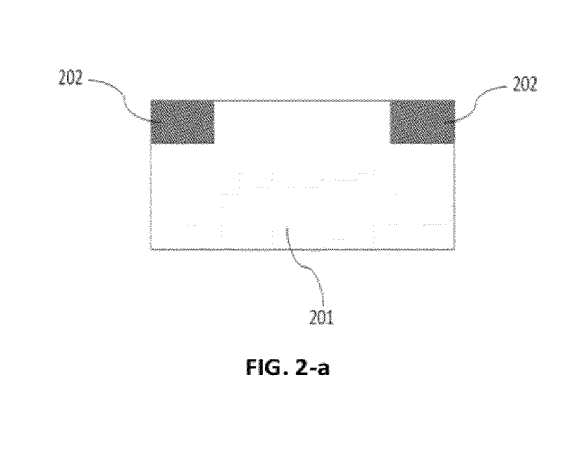

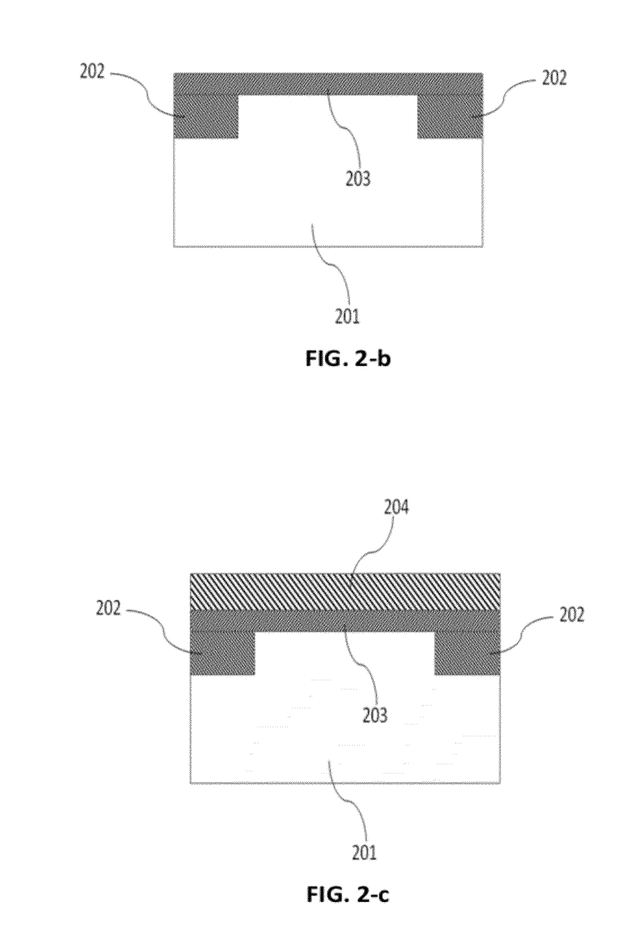

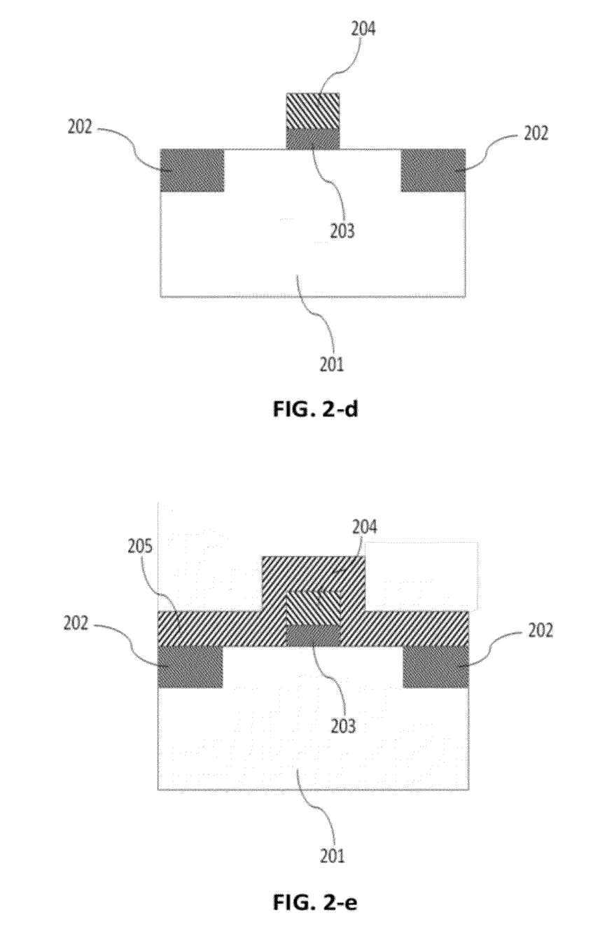

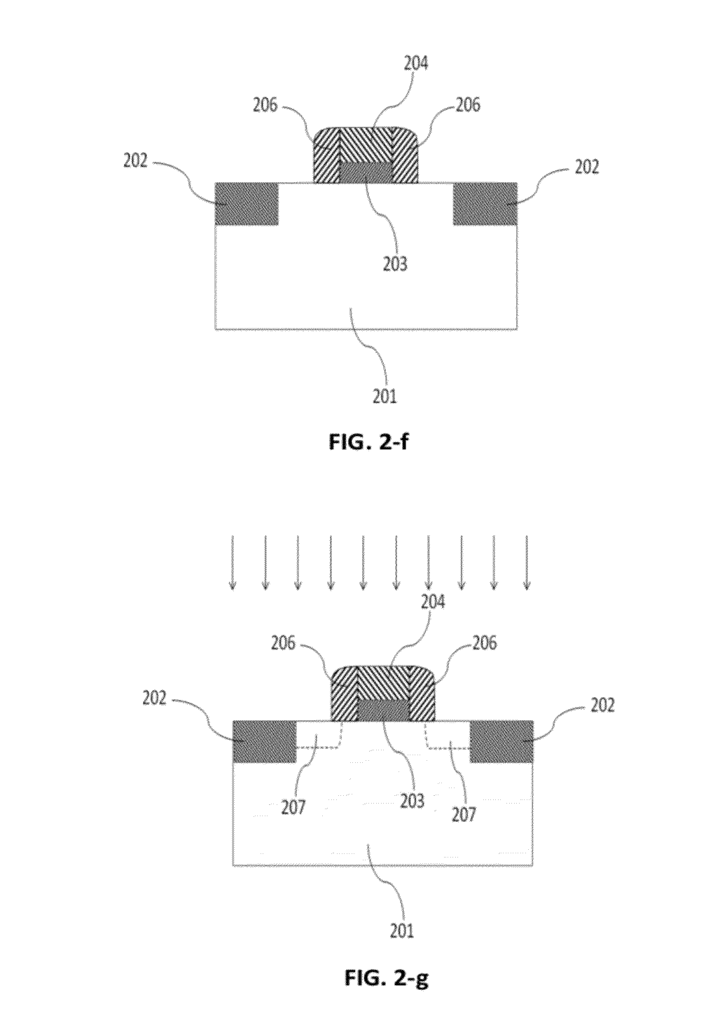

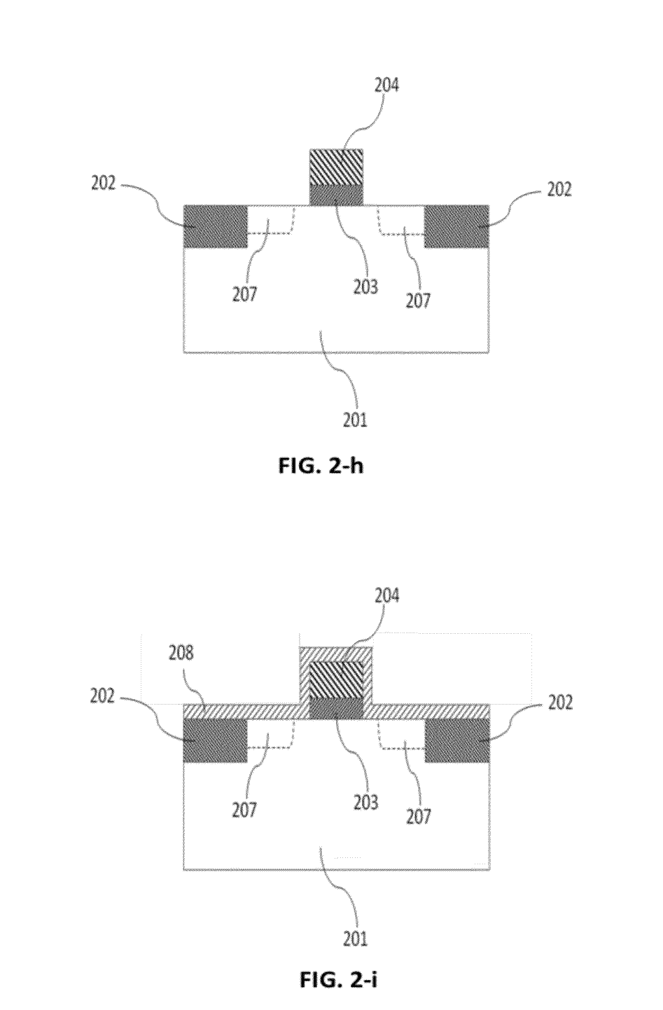

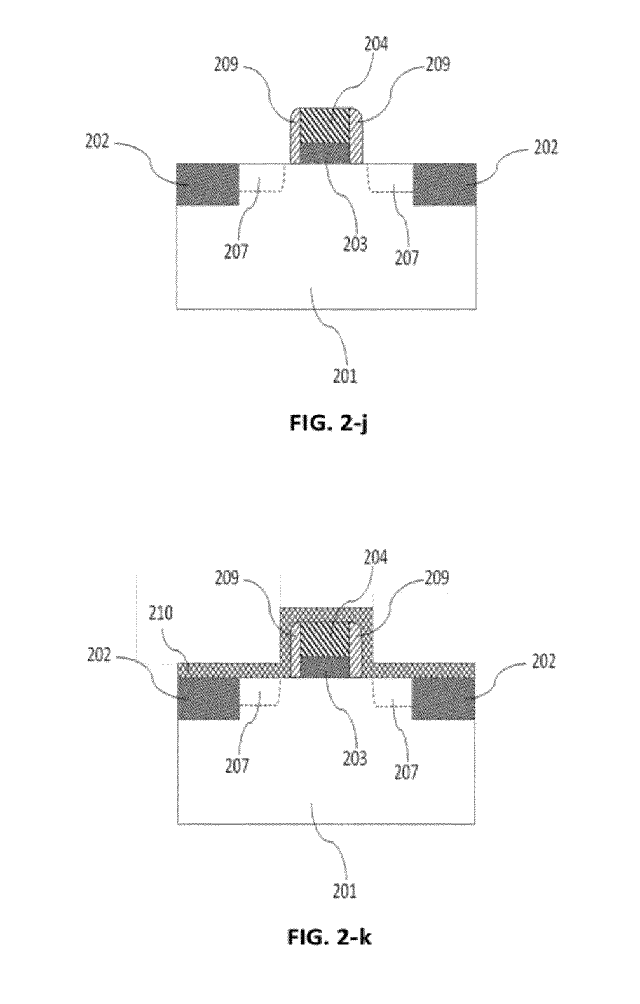

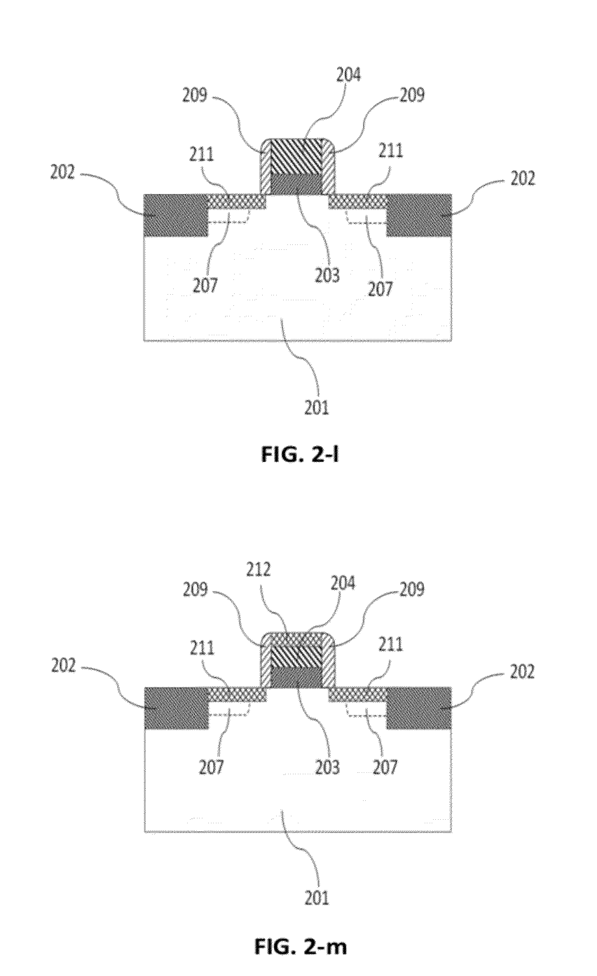

The process for making the mixed junction source/drain field-effect-transistor according to embodiments of the present invention is explained in more detail in the following with reference to FIG. 2-a to FIG. 2-m.

In the following description, the terms “silicon wafer” and “substrate” include any structure with an exposed surface, which may include various integrated circuit structures formed thereon. The term “substrate” can also be understood as including a semiconductor wafer in the middle of a fabrication process, which may include other thin layers formed thereon.

FIG. 2-a is cross-sectional diagram of a substrate according to exemplary processes of the present invention, including a semiconductor substrate 201 and trench isolation dielectric layer 202, upon which the mixed junction source/drain field-effect-transistor is to be formed. Although silicon material is used as an example for the semiconductor substrate in the following descriptions, the semiconductor substrate 201 is not limited to silicon material, and can be germanium, silicon-germanium compound, silicon on oxide (SOI) or germanium on oxide (GOI) structure, or any of the other semiconductor materials. The semiconductor substrate 201 can be P-type, such as one doped with boron or indium, etc., or N-type, such as one doped with phosphorous, arsenic, or antimony, etc. Isolation structures are formed between semiconductor devices on the semiconductor substrate 201 using shallow trench isolation process technologies, and includes insulating dielectrics filling the shallow trench isolation structures. The insulating dielectrics can be silicon dioxide, silicon nitride, or other insulation materials.

As shown in FIG. 2-b, an insulator layer 203 is deposited on the semiconductor substrate 201. The material for the insulator layer 203 can be any of silicon dioxide, silicon nitride, aluminum oxide, a hafnium-containing high-K dielectric, a zirconium-containing high-K dielectric or a combination of two or more thereof. The insulator layer 203 is used as a gate dielectric layer for the mixed junction source/drain field-effect-transistor. The insulator layer 203 can be formed on a surface of the semiconductor substrate 201 using a thermal process or a deposition process.

As shown in FIG. 2-c, a gate electrode layer 2-4 is formed on the insulator layer 203. The gate electrode layer includes at least one conductive layer, which can be polysilicon, titanium nitride, tantalum nitride, tungsten, a metal silicide or a multi-layered structure formed with two or more thereof.

As shown in FIG. 2-d, the electrode layer 204 and insulator layer 203 is patterned etched using photolithography and etching processing to form the gate electrode structure of the mixed junction source/drain field-effect-transistor according to embodiments of the present invention.

As shown in FIG. 2-e, an insulator layer 205 with a thickness of d1 is deposited, which can be silicon dioxide, silicon nitride or a combination thereof, and which should not be made of the same material as the insulating dielectric 202 in the shallow trench isolation.

As shown in FIG. 2-f, the insulator layer 205 is anisotropically etched using a dry etch process, stopping at a point when the electrode layer 204 or the semiconductor substrate 201 is exposed. The part of the insulator layer 205 remaining after the dry etch process for etching the insulator layer 205 forms sidewall structures 206 along a vertical direction of the gate structure.

As shown in FIG. 2-g, with the sidewall structure 206 acting as a mask, ions are implanted into the transistor on two sides of the gate structure. If the semiconductor substrate is P-type, the ions implanted into the source and drain are N-type ions such as phosphorus or arsenic, etc. If the semiconductor substrate is N-type, the ions implanted into the source and drain are P-type ions such as boron or indium, etc. Annealing is performed afterwards to activate the ions. With these steps, P-N junctions 207 are formed between a source region and the semiconductor substrate 201 and between a drain region and the semiconductor substrate 201.

As shown in FIG. 2-h, insulator layer 205 includes a material different from the insulating dielectric 202. The relatively thicker sidewalls 206 on the two sides of the gate electrode can be removed using anisotropic etching, isotropic etching or a combination thereof, in preparation for subsequent metal deposition for the Schottky junction(s).

As shown in FIG. 2-1, after the process steps described above, an insulator layer 208 having a thickness of d2 (d2>d1) is deposited. The insulator layer 208 can be silicon dioxide, silicon nitride or a combination thereof.

As shown in FIG. 2-j, the insulator layer 208 is anisotropically etched using a dry etching process, stopping at a point when a surface of the electrode layer 204 or the semiconductor substrate 201 is exposed. Sidewall structures 209 formed along a vertical direction of the gate structure remain after the dry etching process for etching the insulator layer 208. Sidewalls 209 has a smaller horizontal width than that of sidewalls 206.

As shown in FIG. 2-k, a metal layer 210 is deposited, which can be nickel, cobalt, titanium, platinum or a combination or two or more thereof.

As shown in FIG. 2-1. Annealing is performed to cause the metal to react with exposed silicon substrate, forming a metal silicide. The metal silicide can be nickel silicide, cobalt silicide, titanium silicide, platinum silicide, or a combination of two or more thereof. After removing unreacted part of the metal on the surface, a desired metal silicide layer 211 is obtained. Often, another annealing process is used to make the newly formed metal silicide 211 more stable.

Because the substrate is lightly doped, the parts of the metal silicide 211 near the gate electrode form Schottky junctions with the semiconductor substrate and form Ohmic contacts with the highly doped ion implanted regions.

As shown in FIG. 2-m, if the surface of the gate electrode 204 is covered with polysilicon, metal silicide (s) 212 are also formed on top of the gate electrode.

Using the above processes, a metal-oxide-semiconductor field effect transistor with mixed junction source and drain is formed, which includes a gate electrode structure 203 and 204, isolation structures 202, sidewalls 209 on two sides of the gate electrode structure, semiconductor substrate 201, and source and drain structures having mixed P-N and Schottky junctions. The parts of the metal silicide layer 211 near the gate electrode form Schottky junctions with the semiconductor substrate while forming Ohmicic contacts at the same time with the highly doped regions near the surfaces above the P-N junctions 207. This mixed junction source/drain field-effect-transistor is characterized in that: the switching property of the field-effect-transistor is mainly determined by the Schottky junctions in the mixed junctions so that the field-effect-transistor can be categorized as a Schottky field-effect-transistor, while the main parts of the source and drain regions form P-N junctions with the substrate so that the field-effect-transistor has the characteristics of relatively low source/drain leakage compared with pure Schottky junction field-effect-transistors.

It should be noted that many largely different embodiments could be fashioned without departing from the spirit and scope of the present invention. It is to be understood that besides what is defined in the appended claims, the present invention is not limited by the specific embodiments described in the specification.

We claim:

1. A field effect transistor, comprising: a semiconductor substrate, a gate structure, sidewalls, and source/drain regions having at least one mixed junction, the mixed junction being a combination of a Schottky junction and a P-N junction.

2. The field-effect-transistor according to claim 1, wherein switching property of the field-effect-transistor is determined by the Schottky junction in the mixed junction.

3. The field-effect-transistor according to claim 1, wherein the semiconductor substrate is a silicon substrate, the Schottky junction is formed between a metal silicide material and the semiconductor substrate, and wherein the metal silicide material forms an Ohmic contact with a highly doped region in the P-N junction.

4. A field-effect-transistor according to claim 1, wherein the semiconductor substrate is a germanium substrate, the Schottky junction is formed between a metal germanide material and the semiconductor substrate, the P-N junction is formed by implanting ions of a different dopant type from that used to dope the germanium substrate and by subsequent annealing, the metal germanide material forming an Ohmic contact with a highly doped region in the P-N junction.

5. A method of making the field-effect-transistor according to claim 1, comprising:
providing a semiconductor substrate and forming isolation structures using shallow trench isolation;
forming a first dielectric layer, forming an electrode layer over the first dielectric layer, and forming a gate electrode structure by patterned etching of the electrode layer and the first dielectric layer using photolithography and etch processing;
depositing a second dielectric layer and etching the second dielectric layer using an anisotropic dry etching process, thereby forming first sidewall structures on two sides of the gate structure;
implanting ions to form P-N junctions in the semiconductor substrate, and annealing to activate the ions;
removing the first sidewall structures by etching, depositing a third dielectric layer, and etching the third dielectric layer using an anisotropic etching process, thereby forming second sidewall structures; and
depositing a metal layer, annealing to cause the metal layer to react with the underlying semiconductor substrate to form metal-semiconductor compound, and removing unreacted part of the metal layer.

6. The method according to claim 5, wherein the first dielectric layer is selected from the group consisting of silicon dioxide, silicon nitride, aluminum oxide, hafnium-containing high-K dielectrics, zirconium-containing high-K dielectrics, and combinations of two or more thereof.

7. The method according to claim 5, wherein the electrode layer includes at least one conductive layer, the conductive layer being any of polysilicon, titanium nitride, tantalum nitride, tungsten, and metal silicides, or a multilayer structure of two or more thereof.

8. The method according to claim 5, wherein the metal-semiconductor compound forms Schottky junctions with the semiconductor substrate while at the same time forming Ohmic contacts with highly doped regions in the P-N junctions.

9. The method according to claim 5, wherein the semiconductor substrate is a silicon substrate, the metal layer is selected from the group consisting of nickel, cobalt, titanium, platinum, and combinations of two or more thereof, and wherein the metal-semiconductor compound is selected from the group consisting of nickel silicide, cobalt silicide, titanium silicide, platinum silicide, and combinations or two or more thereof.

10. The method according to claim 5, wherein the semiconductor substrate is a germanium substrate, the metal layer is selected from the group consisting of nickel, cobalt, titanium, platinum, and combinations of two or more thereof, and wherein the metal-semiconductor compound is selected from the group consisting of nickel germanide, cobalt germanide, titanium germanide, platinum germanide, and combinations or two or more thereof.
